(19) United States
(12) Patent Application Publication
(10) Pub. No.: US 2026/0146645 A1
(43) Pub. Date: May 28, 2026

(54) HYDROSTATIC GAS BEARING DEVICE

(71) Applicant: KYOCERA Corporation, Kyoto-shi, Kyoto (JP)

(72) Inventor: Koji AKASHI, Hikone-shi, Shiga (JP)

(21) Appl. No.: 19/123,221

(22) PCT Filed: Oct. 24, 2023
(86) PCT No.: PCT/JP2023/038377

§ 371 Date: Apr. 22, 2025

(30) Foreign Application Priority Data
Oct. 26, 2022 (JP) 2022-171335

(51) Int. Cl. F16C 17/10

(52) U.S. Cl. CPC F16C 17/102

(57) ABSTRACT

A hydrostatic gas bearing device according to the present disclosure includes a movable member and a fixed member. A recessed portion is located at a bearing surface of a base of the movable member or the fixed member, and an opening portion of a gas supply hole is located at a bottom surface of the recessed portion. A porous body serving as a gas ejection portion is located in the recessed portion while not protruding from the bearing surface. In a surface of the porous body, a first groove extending from a central region of the surface to an outer periphery of the porous body is located. A second groove communicating with the first groove is located in the bearing surface of the base.

### TECHNICAL FIELD

The present disclosure relates to a hydrostatic gas bearing device.

### BACKGROUND OF INVENTION

In a semiconductor manufacturing device such as a mask exposure device, an air slide has been used as a device for scanning and positioning a stage with high accuracy. Examples of such an air slide include those adopting an orifice restriction, a surface restriction, or the like. Such an air slide causes, when foreign matter enters a gas supply hole, the supply amount of a gas to change to decrease its rigidity, failing to stabilize the dynamic attitude of the moving body.

As described in Patent Document 1, a static pressure bearing device that provides a porous member in a bearing portion and provides an air supply hole and an exhaust groove for exhausting the pressurized fluid in the porous member is used. The static pressure bearing device described in Patent Document 1 can increase the ejection region of the compressed gas. This can enhance the bearing rigidity but generates vibration due to the compression effect of the gas in the porous body. In a semiconductor manufacturing process, in particular, reduction in micro vibration to the stage has been awaited for a more highly integrated semiconductor element with higher performance.

### CITATION LIST

### Patent Literature

Patent Document 1: JP 5-10330 A

### SUMMARY

### Solution to Problem

A hydrostatic gas bearing device according to the present disclosure includes a movable member and a fixed member. A recessed portion is located at a bearing surface of a base of the movable member or the fixed member, and an opening portion of a gas supply hole is located at a bottom surface of the recessed portion. A porous body serving as a gas ejection portion is located in the recessed portion while not protruding from the bearing surface. In a surface of the porous body, a first groove extending from a central region of the surface to an outer periphery of the porous body is located. A second groove communicating with the first groove is located in the bearing surface of the base.

### BRIEF DESCRIPTION OF THE DRAWINGS

FIG. 1 is an explanatory view illustrating an example in which a hydrostatic gas bearing device according to one embodiment of the present disclosure is provided in a linear guide device.

FIG. 2A is a plan view illustrating a main portion of the hydrostatic gas bearing device according to one embodiment of the present disclosure.

FIG. 2B is a plan view illustrating a variation of the main portion of the hydrostatic gas bearing device according to one embodiment of the present disclosure.

FIG. 2C is a plan view illustrating another variation of the main portion of the hydrostatic gas bearing device according to one embodiment of the present disclosure.

FIG. 3 is an explanatory view illustrating a cross section taken along a line X-X illustrated in FIG. 2A.

FIG. 4 is a plan view illustrating the bottom surface of the recessed portion.

FIG. 5 is a plan view illustrating a main portion of a hydrostatic gas bearing device according to another embodiment of the present disclosure.

FIG. 6 is a plan view illustrating a main portion of a hydrostatic gas bearing device according to still another embodiment of the present disclosure.

FIG. 7 is a plan view illustrating a main portion of a hydrostatic gas bearing device according to still another embodiment of the present disclosure.

FIG. 8 is a plan view illustrating a main portion of a hydrostatic gas bearing device according to still another embodiment of the present disclosure.

FIG. 9A is a plan view illustrating a main portion of a hydrostatic gas bearing device according to still another embodiment of the present disclosure.

FIG. 9B is a plan view illustrating a main portion of a hydrostatic gas bearing device according to still another embodiment of the present disclosure.

FIG. 10 is a plan view illustrating a main portion of a hydrostatic gas bearing device according to still another embodiment of the present disclosure.

FIG. 11A is a plan view illustrating a main portion of a hydrostatic gas bearing device according to still another embodiment of the present disclosure.

FIG. 11B is a plan view illustrating a main portion of a hydrostatic gas bearing device according to still another embodiment of the present disclosure.

### DESCRIPTION OF EMBODIMENTS

As described above, the conventional static pressure gas bearing device has a problem that vibration occurs due to the compression effect of the gas in the porous body. In response to this, there is a demand for a hydrostatic gas bearing device capable of reducing a decrease in rigidity due to micro vibration and clogging of a gas supply hole.

The hydrostatic gas bearing device according to the present disclosure having the above-described configuration can reduce a decrease in rigidity due to micro vibration and clogging of the gas supply hole.

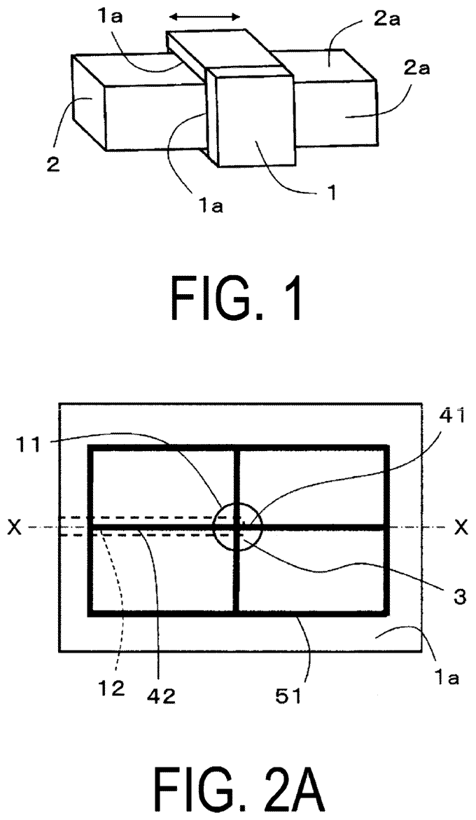

A hydrostatic gas bearing device according to one embodiment of the present disclosure will be described with reference to FIGS. 1 to 4. FIG. 1 is an explanatory view illustrating an example in which a hydrostatic gas bearing device according to one embodiment of the present disclosure is provided in a linear guide device. The hydrostatic gas bearing device according to one embodiment includes a movable member 1 and a fixed member 2.

The movable member 1 is provided to surround the fixed member 2 having a substantially quadrangular prism shape. The movable member 1 and the fixed member 2 are located to have a gap and are not in contact with each other. A hydrostatic gas layer is formed by ejecting compressed gas from a bearing surface la of the base of the movable member 1 or a bearing surface 2a of the base of the fixed member 2. This can move, in a state where the movable member 1 and the fixed member 2 are not in contact with each other, the movable member 1 along the fixed member 2 using another driving means (not illustrated).

The movable member 1 and the fixed member 2 are formed of, for example, a ceramic or a metal. Examples of the ceramic forming the movable member 1 and the fixed member 2 include a ceramic having alumina, zirconia, silicon carbide, silicon nitride, or aluminum nitride as a main component. Examples of the metal include aluminum and stainless steel. The movable member 1 and fixed member 2 may be formed of the same material or may be formed of different materials.

In the present specification, the “main component” means a component that accounts for 80 mass% or more among the total of 100 mass% of the components constituting the ceramic. The identification of each component contained in the ceramic may be performed with an X-ray diffractometer using a CuKa beam, and the content of each component may be determined, for example, with an Inductively Coupled Plasma (ICP) emission spectrophotometer or a fluorescence X-ray spectrometer.

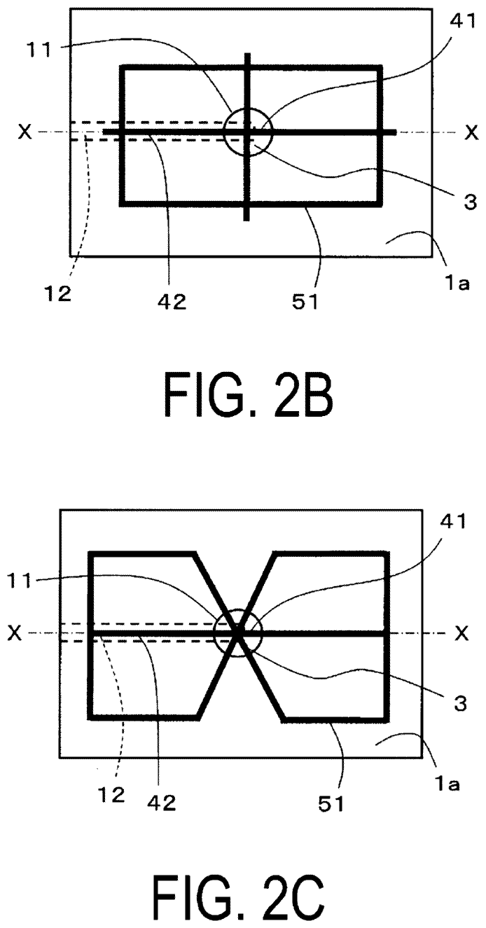

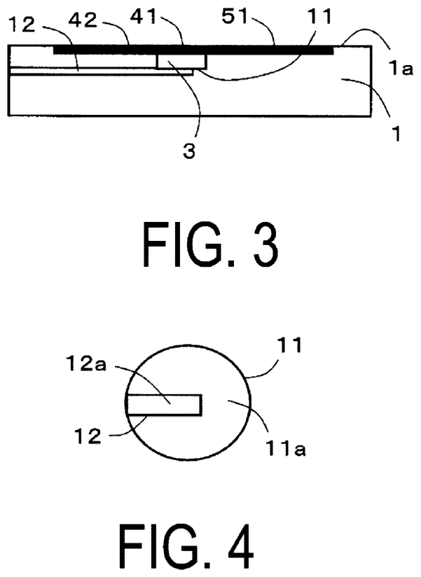

Hereinafter, an embodiment in which gas is ejected from the bearing surface 1a of the base of the movable member 1 will be described with reference to FIGS. 2A to 4. FIG. 2A is a plan view illustrating a main portion of the hydrostatic gas bearing device according to one embodiment of the present disclosure. FIG. 3 is an explanatory view illustrating a cross section taken along a line X-X illustrated in FIG. 2A. FIG. 4 is a plan view illustrating a bottom surface 11a of a recessed portion 11. As illustrated in FIGS. 2A to 4, the recessed portion 11 and a gas supply hole 12 including an opening portion 12a in a part of the bottom surface 11a of the recessed portion 11 are located in the bearing surface 1a of the base of the movable member 1.

A porous body 3 is located in the recessed portion 11. The thickness of the recessed portion 11 is not limited, and is, for example, 1 mm or more and 10 mm or less. The porous body 3 is a member serving as a gas ejection portion. The porous body 3 is fixed in the recessed portion 11 not to protrude from the bearing surface la of the base of the movable member 1.

As illustrated in FIGS. 3 and 4, the gas supply hole 12 communicating with the outside of the movable member 1 is connected to the bottom surface 11a of the recessed portion 11. As illustrated in FIG. 4, the gas supply hole 12 includes an opening portion 12a at a part of the bottom surface 11a of the recessed portion 11. A gas is supplied from the outside of the movable member 1 through the gas supply hole 12 to the porous body 3 serving as the ejection portion. The gas supply hole 12 may be, for example, a lateral hole formed from the side surface of the base, a vertical hole formed from the bottom surface of the base, or a combination of a lateral hole formed from the side surface of the base and a vertical hole connecting the lateral hole and the bottom surface 11a.

The porous body 3 is formed of, for example, a ceramic. Examples of such ceramic include ceramic containing alumina, zirconia, silicon carbide, silicon nitride, or aluminum nitride as a main component. The porous body 3 may be formed of the same material as that of a member in which the recessed portion 11 is located (in one embodiment, the movable member 1). When the porous body 3 is formed of the same material as that of the member in which the recessed portion 11 is located, a difference in thermal expansion coefficient is less likely to occur and stress is less likely to occur even when temperature changes. Accordingly, turbulence due to deformation or the like is less likely to occur, and micro vibration due to turbulence is further reduced. The porosity of the porous body 3 is not limited and may be 20% or more and 50% or less, for example. The average particle diameter of the porous body 3 is not limited and may be 10 μm or more and 100 μm or less, for example.

The porosity of the porous body 3 is determined by a mercury porosimetry method, for example. The mercury porosimetry method is a method in which mercury is intruded into pores of the porous body 3 (sample) using a mercury intrusion porosimeter (mercury porosimetry method) to determine the porosity, and the porosity may be determined in accordance with JIS R 1655-2003.

The thickness of the porous body 3 is not limited as long as the porous body 3 does not protrude from the recessed portion 11. For example, the upper surface of the porous body 3 may be flush with the bearing surface of the base (in one embodiment, the bearing surface la of the base of the movable member 1). When the upper surface of the porous body 3 and the bearing surface of the base are flush with each other, turbulence due to a step between the upper surface of the porous body 3 and the bearing surface of the base is less likely to occur. As a result, the micro vibration due to the turbulence is further reduced.

At least the bottom surface of the porous body 3 may be bonded to the bottom surface 11a of the recessed portion 11. When at least the bottom surface of the porous body 3 is bonded to the bottom surface 11a of the recessed portion 11, the fixing strength of the porous body 3 can be increased. The bonding method is not limited, and for example, bonding is performed using an epoxy-based adhesive such as Araldite (registered trademark, available Huntsman Japan) and TorrSeal (available from Agilent Technologies). The porous body 3 may be bonded to the entire surface of the recessed portion 11 other than the opening portion 12a of the gas supply hole 12. When the porous body 3 is bonded to the entire surface of the recessed portion 11 other than the opening portion 12a of the gas supply hole 12, the gas more easily flows from the gas supply hole 12 to a first groove 41 described later. As a result, the gas is easily dispersed in the entire porous body 3, and the micro vibration is further reduced.

A plurality of first grooves 41 having a radial shape are provided on the surface of the porous body 3. In a plan view, as illustrated in FIG. 2A, the first groove 41 is formed extending outward from the central region of the porous body 3. The first groove 41 is not limited as long as at least one first groove 41 is formed so as to extend from the central region of the surface of the porous body 3 to the outer periphery of the porous body 3. From the viewpoint of uniformizing the in-plane pressure distribution, the number of the first grooves 41 may be three or more and eight or less. The width and the depth of the first groove 41 is not limited. For example, the width may be 0.5 mm or more and 2 mm or less. For example, the depth may be 0.005 mm or more and 0.05 mm or less.

The cross-sectional shape perpendicular to the length direction of the first groove 41 is not particularly limited. The cross-sectional shape may be, for example, a U shape in which the opening portion and the bottom portion of the groove have the same width, a V shape in which the width of the opening portion of the groove is larger than the width of the bottom portion, or a U shape (a shape having a curved line at the bottom portion). In particular, from the viewpoint of reducing the turbulence of the gas, the cross-sectional shape may be a V shape or a U shape in which the width of the opening portion of the groove is larger than the width of the bottom portion. When grooves having the same cross-sectional area but different widths and depths are compared, the surface area of a groove is larger when the groove is elongated (the width is smaller than the depth). Accordingly, since the loss due to the resistance is likely to increase, the width of the groove is preferably larger than the depth thereof. However, if the depth is too large with respect to the width, the micro vibration tends to increase. Thus, the width is preferably 100 times or less of the depth.

The angles formed by adjacent two first grooves 41 of the plurality of first grooves 41 may be the same. Having such a configuration makes the gas flowing through the first groove 41 more uniform. As a result, variations in the flow of the gas are reduced. In FIG. 2A, the four first grooves 41 are formed at intervals of 90°.

A plurality of second grooves 42 communicating with the first grooves 41 are provided in the bearing surface of the base (in one embodiment, the bearing surface la of the base of the movable member 1).

Since the second groove 42 communicates with the first groove 41, the second groove 42 is located to be aligned with the first groove 41 as illustrated in FIG. 2A. The width and depth of the second groove 42 are, for example, the same as the width and depth of the first groove 41.

The hydrostatic gas bearing device according to one embodiment includes the first groove 41 and the second groove 42. This can move the gas ejected from the porous body 3d to the second groove 42 by the first groove 41. As a result, the gas can be moved to the base of the movable member 1. Therefore, a floating force can be generated at the base of the movable member 1, and the floating force is stabilized to reduce micro vibration.

A first intersecting groove 51 intersecting the second groove 42 may be provided in the bearing surface la of the base. With such a configuration, the gas flowing through the second groove 42 can be dispersed also in the direction intersecting the second groove 42, and the micro vibration is further reduced. “Intersection” includes double intersection, triple intersection, and quadruple intersection. The double intersection means a structure directed in two directions from an intersection point, and examples thereof include an L-shape. The triple intersection means a structure directed in three directions from an intersection point, and examples thereof include a T-shape and a Y-shape. The quadruple intersection means a structure directed in four directions from an intersection point, and examples thereof include a cross-shape, an X-shape, and an interleaved shape.

The first intersecting groove 51 may be connected at the terminal end of the second groove 42, or may be connected in the middle of the second groove 42. The terminal end of the first intersecting groove 51 may be connected to the second groove 42, or the middle of the first intersecting groove 51 may be connected to the second groove 45.

The first intersecting groove 51 may connect the adjacent second grooves 45 to each other. This causes the gas to be likely to be uniformly supplied to the bearing surface 1a. In FIG. 2A, the first intersecting groove 51 is located to connect the terminal ends of the second grooves 42. In FIG. 2A, the first intersecting groove 51 is formed in a rectangular shape in accordance with the rectangular bearing surface la when viewed in a plan view. As described above, the first intersecting groove 51 is preferably formed in parallel with the profile shape of the bearing surface 1a. However, the shape of the first intersecting groove 51 is not limited as long as the first intersecting groove 51 is formed to connect the second grooves 42 to each other.

For example, as illustrated in FIG. 2A, the first intersecting groove 51 may be formed in an annular shape to connect the second grooves 42 to each other. The first intersecting groove 51 may have a shape similar to that of the bearing surface 1a of the base (the first intersecting groove 51 having a rectangular shape in the case of the bearing surface la having a rectangular shape as illustrated in FIG. 2A). This causes the gas to be likely to be uniformly supplied to the bearing surface la. The width and the depth of the first intersecting groove 51 are, for example, the same as the width and the depth of the first groove 41.

In FIG. 2A, the first intersecting groove 51 is formed in an annular shape to connect the terminal ends of the second groove 42. However, as illustrated in FIG. 2B, the first intersecting groove 51 may be formed in an annular shape to connect portions other than the terminal ends of the second groove 42. FIG. 2B is a plan view illustrating a variation of the main portion of the hydrostatic gas bearing device according to one embodiment of the present disclosure.

The first intersecting groove 51 may have a partially annular structure as illustrated in FIG. 2C (in the present disclosure, such a partially annular structure is also referred to as an annular structure). FIG. 2C is a plan view illustrating another variation of the main portion of the hydrostatic gas bearing device according to one embodiment of the present disclosure.

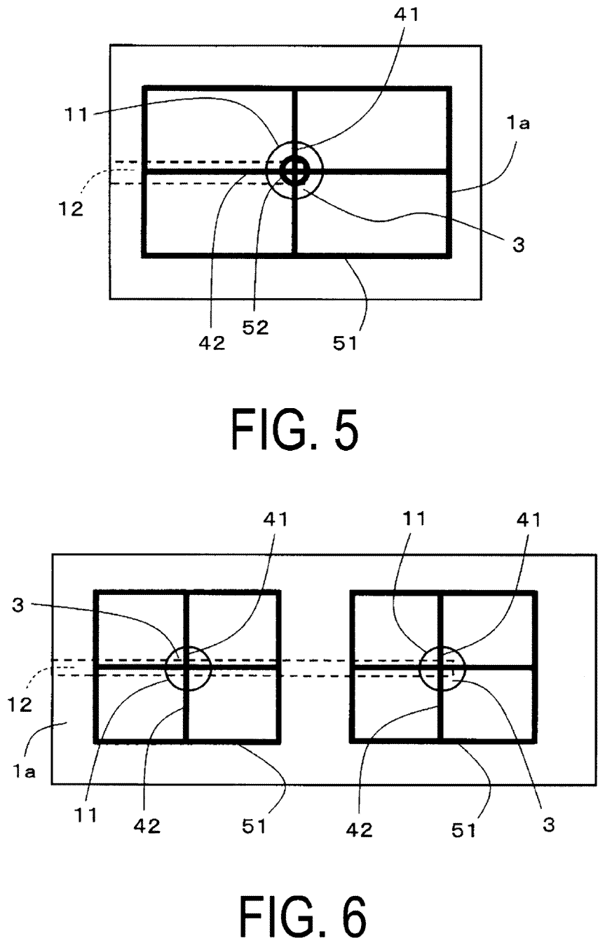

As illustrated in FIG. 5, the porous body 3 may be further provided with at least one second intersecting groove 52 intersecting and connecting with the first groove 41. FIG. 5 is a plan view illustrating a main portion of a hydrostatic gas bearing device according to another embodiment of the present disclosure. The second intersecting groove 52 are provided, thus reducing variation in the flow of the gas. The second intersecting groove 52 may connect between the plurality of first grooves 41. This causes the gas to be likely to be uniformly supplied to the surface of the porous body 3.

The second intersecting groove 52 may have a similar shape to the porous body 3 in a plan view. In FIG. 5, in a plan view, the porous body 3 has a circular shape, and the second intersecting groove 52 also has a circular shape (annular shape). In FIG. 5, the second intersecting groove 52 has a circular shape (annular shape). However, the shape of the second intersecting groove 52 is not limited to an annular shape as long as the second intersecting groove 52 can connect between the first grooves 41.

Arithmetic mean roughness Ra of the bearing surface of the base (the bearing surface 1a of the base of the movable member 1), the surface of the porous body 3 and the inner wall surface of each groove is not limited. For example, the arithmetic mean roughness Ra of the bearing surface of the base may be smaller than the arithmetic mean roughness Ra of the inner wall surface of the second groove 42. When the arithmetic mean roughness Ra of the bearing surface of the base is smaller than the arithmetic mean roughness Ra of the inner wall surface of the second groove 42, the inner wall surface of the second groove 42 is relatively rough and the velocity of the flowing gas can be reduced. As a result, the vibration is absorbed and the micro vibration is reduced. On the other hand, the bearing surface of the base is relatively smooth. Therefore, the gas easily spreads uniformly over the bearing surface (the bearing surface 1a), and the movable member 1 can be moved smoothly.

The arithmetic mean roughness Ra of the surface of the porous body 3 may be smaller than the arithmetic mean roughness Ra of the inner wall surface of the first groove 41. When the arithmetic mean roughness Ra of the surface of the porous body 3 is smaller than the arithmetic mean roughness Ra of the inner wall surface of the first groove 41, the inner wall surface of the first groove 41 is relatively rough, and the velocity of the flowing gas can be reduced. As a result, the vibration is absorbed and the micro vibration is reduced. On the other hand, the surface of the porous body 3 is relatively smooth. Therefore, the gas easily spreads uniformly over the surface of the porous body 3, and the movable member 1 can be moved smoothly.

The arithmetic mean roughness Ra of the bearing surface of the base may be 0.1 μm or more and 1.0 μm or less, for example. The arithmetic mean roughness Ra of the surface of the porous body 3 may be 0.1 μm or more and 2.0 μm or less, for example. The arithmetic mean roughness Ra of the inner wall surface of the first groove 41 may be 0.5 μm or more and 3.0 μm or less, for example. The arithmetic mean roughness Ra of the inner wall surface of the second groove 42 may be 1.0 μm or more and 4.0 μm or less, for example.

The arithmetic mean roughness Ra of the bearing surface of the base, the surface of the porous body 3, and the inner wall surface of each groove can be measured in accordance with JIS B 0601:2001 using a shape analysis laser microscope (VK-X 1100 or a successor model thereof available from KEYENCE CORPORATION). As measurement conditions, the measurement multiplication factor is 240 times, the cut-off value as is absent, the cut-off value λc is 0.08 mm, and the cut-off value λs is absent. A measurement range of 1420 μum ×1070 μm may be set for one measurement target surface, and four measurement ranges may be set from the measurement target surface. The surface roughness may be measured by drawing four lines to be measured at substantially equal intervals in each measurement range. The length of a single line to be measured is 1320 μm.

The cross-sectional area of the first groove 41 may be equal to or greater than the cross-sectional area of the second groove 42. The porous body 3 has a tendency that pressure is increased due to a throttle effect (molecules are compressed by passing a fluid through a fine hole) by the fine hole and ventilation resistance is increased. Thus, with the configuration in which the surface of the porous body 3 has grooves as described above, the ventilation resistance of the first groove 41 can be reduced, and the gas can be smoothly supplied to the second groove 42. The cross-sectional area of each of the first groove 41 and the second groove 42 can be set to a desired cross-sectional area by changing at least one of the depth and the width of each groove.

The cross-sectional area of the first groove 41 means the area of a region surrounded by a virtual plane passing through the surface of the porous body 3 and the inner wall of the first groove 41 in a cross section obtained by cutting the first groove 41 perpendicularly to the extending direction thereof. The cross-sectional area of the second groove 42 means an area of a region surrounded by a virtual plane passing through the bearing surface of the base and the inner wall of the second groove 42 in a cross section obtained by cutting the second groove 42 perpendicularly to the extending direction thereof.

As illustrated in FIG. 6, a plurality of recessed portions 11 may be located at the bearing surface of the base (the bearing surface la of the base of the movable member 1), and a plurality of porous bodies 3 may be fixed to the respective plurality of recessed portions 11. FIG. 6 is a plan view illustrating a main portion of a hydrostatic gas bearing device according to still another embodiment of the present disclosure. The plurality of porous bodies 3 are fixed to the respective plurality of recessed portions 11, thus making gas ejection in the bearing surface uniform. As a result, a structure fixed in this way can be applied, for example, to a bearing surface having a larger area.

As illustrated in FIG. 6, in the embodiment in which the plurality of porous bodies 3 are fixed to the respective plurality of recessed portion 11, when one porous body 3, the first groove 41 provided in the porous body 3, the second groove 42 communicating with the first groove 41, and the first intersecting groove 51 intersecting the second groove 42 are regarded as one unit, a plurality of units may be located at the bearing surface la, and each unit may be independently located while not contacting each other.

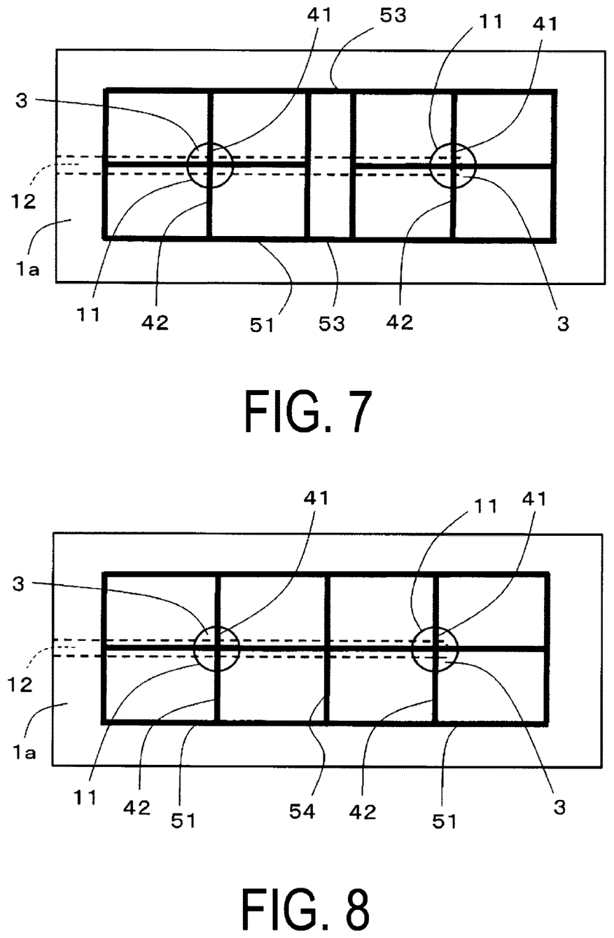

When each unit is independently located, adjacent units may be connected via a communication groove 53 as illustrated in FIG. 7. FIG. 7 is a plan view illustrating a main portion of a hydrostatic gas bearing device according to still another embodiment of the present disclosure. When adjacent units are connected via the communication groove 53, variation in the flow of the gas in each unit is reduced. As a result, the gas easily spreads uniformly over the bearing surface (the bearing surface 1a).

As illustrated in FIG. 8, adjacent units may be connected by sharing a part of the first intersecting groove 51 which is a part of one unit and a part of the first intersecting groove 51 which is a part of the other unit by a shared groove 54. In other words, among the adjacent units, a part of the first intersecting groove 51 of one unit may include the shared groove 54, and a part of the first intersecting groove 51 of the other unit may also include the shared groove 54. This reduces variations in the flow of gas between adjacent porous bodies 3. As a result, the gas easily spreads uniformly over the bearing surface (the bearing surface 1a).

The method of forming the first groove 41 and the second intersecting groove 52 on the surface of the porous body 3 and the method of forming the second groove 42, the first intersecting groove 51, and the communication groove 53 on the bearing surface of the base (the bearing surface la of the base of the movable member 1) are not limited as long as they are methods of forming grooves.

For example, each groove may be formed by grinding or polishing after the porous body 3 and the base of the movable member 1 (or the base of the fixed member 2) are produced, or each groove may be formed in advance when the porous body 3 and the base are produced. As a method of forming each groove in advance, when the porous body 3 and the base are formed of a ceramic, a precursor (molded body) in which a portion to be each groove is formed may be obtained, and the precursor may be fired. Alternatively, each groove may be formed after the porous body 3 is fixed to the recessed portion 11 of the base. In this case, the first groove 41 and the second groove 42 communicating with the first groove 41 are integrally formed. This improves the positional accuracy between the first groove 41 and the second groove 42.

The hydrostatic gas bearing device according to the present disclosure is not limited to the hydrostatic gas bearing device according to the embodiment described above. In the hydrostatic gas bearing device according to the above-described embodiment, the first intersecting groove 51 that connects the terminal ends of the second grooves 42 is provided. However, in the hydrostatic gas bearing device according to the present disclosure, in addition to the first intersecting groove, an additional intersecting groove may be provided between the first intersecting groove and the porous body. The additional intersecting groove may be provided in at least one round, and may be provided in an annular shape concentric with the first intersecting groove.

In the hydrostatic gas bearing device according to another embodiment described above, two units are illustrated, each including one porous body 3, the first groove 41 provided in the porous body 3, the second groove 42 communicating with the first groove 41, and the first intersecting groove 51 connecting the terminal ends of the second grooves 42.

However, three or more of the units may be present. The units may be located linearly, vertically and horizontally in a lattice pattern, or randomly.

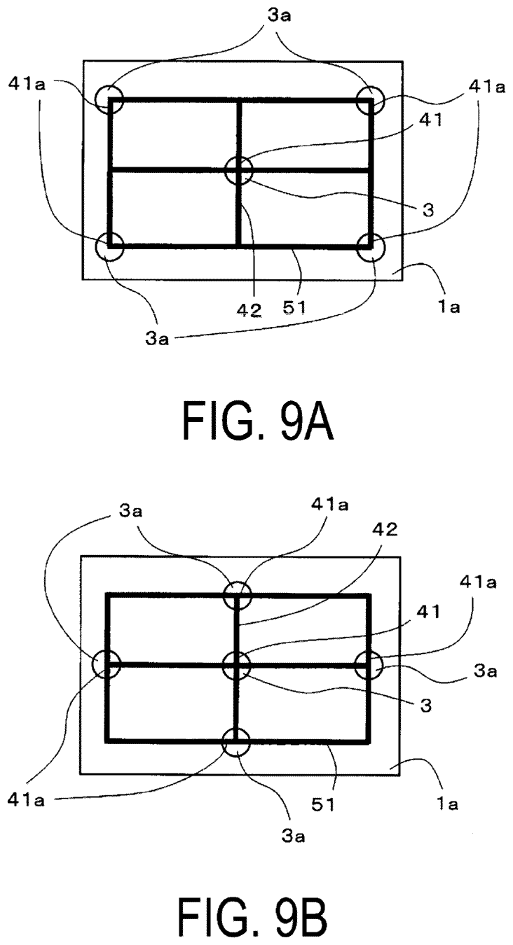

FIG. 9A is a plan view illustrating a main portion of a hydrostatic gas bearing device according to still another embodiment of the present disclosure. In the hydrostatic gas bearing device in FIG. 2A, another porous body 3a and another first groove 41a located on another porous body 3a may be located in the middle of the first intersecting groove 51. Even in such a case, it can be said that the adjacent second grooves 42 are connected by the first intersecting groove 51.

FIG. 9B is a plan view illustrating a main portion of a hydrostatic gas bearing device according to still another embodiment of the present disclosure. In the hydrostatic gas bearing device illustrated in FIG. 2A, another porous body 3a and another first groove 41a located on another porous body 3a may be located at the connecting portion between the second groove 42 and the first intersecting groove 51. Even in such a case, it can be said that the first intersecting groove 51 intersects the second groove 42.

The number of the porous bodies to which the gas is supplied can be increased by the configurations illustrated in FIGS. 9A and 9B. This can uniformly flow the gas over the bearing surface, further reducing the micro vibration.

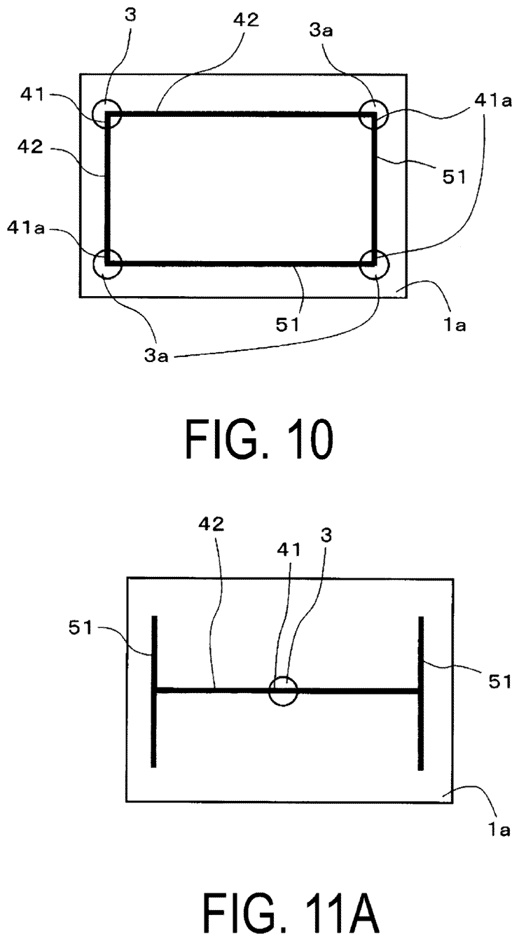

FIG. 10 is a plan view illustrating a main portion of a hydrostatic gas bearing device according to still another embodiment of the present disclosure. It can be said that the hydrostatic gas bearing device of FIG. 10 includes the porous body 3, the first groove 41 located on the porous body 3, the second groove 42 communicating with the first groove 41, and the first intersecting groove 51 intersecting the second groove 42. In FIG. 10, it can be said that another porous body 3a and another first groove 41a located on the porous body 3a are located at the connecting portion between the second groove 42 and the first intersecting groove 51. Even in such a configuration, the floating force of the movable member 1 is stabilized and the micro vibration is reduced.

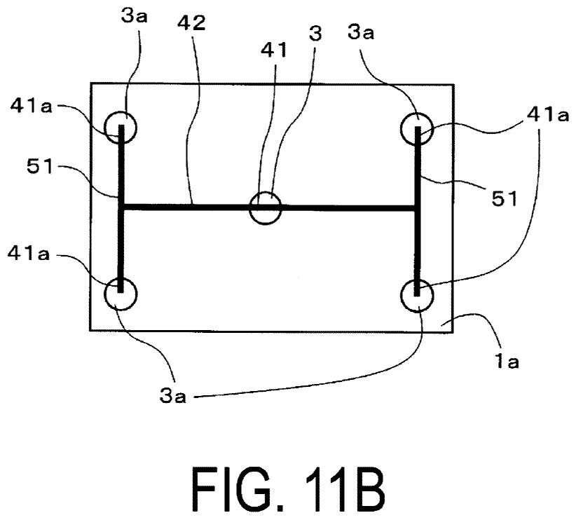

FIG. 11A is a plan view illustrating a main portion of a hydrostatic gas bearing device according to still another embodiment of the present disclosure. The hydrostatic gas bearing device illustrated in FIG. 11A includes the porous body 3, the first groove 41 located on the porous body 3, the second groove 42 communicating with the first groove 41, and the first intersecting groove 51 intersecting the second groove 42. As illustrated in FIG. 11A, the first intersecting groove 51 may not have an annular structure.

FIG. 11B is a plan view illustrating a main portion of a hydrostatic gas bearing device according to still another embodiment of the present disclosure. In FIG. 11B, another porous body 3a and another first groove 41a located on another porous body 3a are located at the terminal end of the first intersecting groove 51 in the hydrostatic gas bearing device in FIG. 11A. Even in such a case, it can be said that the first intersecting groove 51 intersects the second groove 42. The floating force of the movable member 1 is stabilized and the micro vibration is reduced even in the configurations illustrated in FIGS. 11A and 11B.

### EXAMPLES

Hereinafter, the hydrostatic gas bearing device according to the present disclosure will be described specifically based on examples and comparative examples, but the hydrostatic gas bearing device according to the present disclosure is not limited to the examples described below.

### Example 1

First, a hydrostatic gas bearing device as illustrated in FIG. 1 was produced. The movable member 1 included in the hydrostatic gas bearing device of Example 1 was made of alumina, and was manufactured using alumina having a purity of 99.5 mass%. The dimensions of the four bearing surfaces 1a are 100 mm wide and 100 mm long in the direction of movement, respectively.

Each of the four bearing surfaces la includes one unit including the porous body 3, the first groove 41, the second groove 42, and the first intersecting groove 51 as illustrated in FIG. 2A. The second groove 42 and the first intersecting groove 51 both have widths of 1 mm and depths of 0.02 mm. The first intersecting groove 51 has a square-shaped annular structure in a plan view. In the first intersecting groove 51, the length in the direction orthogonal to the moving direction of the movable member 1 is 50 mm, and the length in the moving direction of the movable member 1 is 50 mm.

The porous body 3 is made of alumina having a purity of 99.5 mass%, and has an average particle diameter of 80 μm and a porosity of 40%. The porous body 3 has a diameter of 10 mm. The first groove 41 located in the porous body 3 has a width of 1 mm and a depth of 0.02 mm.

The fixed member 2 included in the hydrostatic gas bearing device of Example 1 was made of alumina, and was produced using alumina having a purity of 99.5 mass%. The longitudinal and lateral lengths of the fixed member 2 are 80 mm, and the length in the longitudinal direction (the length in the direction in which the movable member 1 moves) is 300 mm.

### COMPARATIVE EXAMPLE 1

A hydrostatic gas bearing device was produced in the same manner as in Example 1, except that the porous body 3 used in Example 1 was replaced by an orifice restriction having an opening diameter of 0.2 mm.

In each of the hydrostatic gas bearing devices of Example 1 and Comparative Example 1, a compressed gas was supplied to the gas supply hole 12 of the movable member 1 at 4 kgf/cm², and the rigidity and micro vibration were measured. The rigidity was measured by measuring the amount of change in flying height when a load was loaded. The micro vibration was measured by measuring a micro-displacement of the moving body using an electrostatic capacitance displacement meter.

The hydrostatic gas bearing device of Example 1 had rigidity comparable to that of the hydrostatic gas bearing device of Comparative Example 1. On the other hand, the micro vibration of the hydrostatic gas bearing device of Example 1 could be reduced to about 1/10 of that of the hydrostatic gas bearing device of Comparative Example 1.

The embodiments of the present disclosure have been described above. However, the invention according to the present disclosure is not limited to the above-described embodiments, and various changes or improvements can be made within the scope of the present disclosure described in (1) below.

(1) A hydrostatic gas bearing device according to the present disclosure includes a movable member and a fixed member. A recessed portion is located at a bearing surface of a base of the movable member or the fixed member, and an opening portion of a gas supply hole is located at a bottom surface of the recessed portion. A porous body serving as a gas ejection portion is located in the recessed portion while not protruding from the bearing surface. In a surface of the porous body, a first groove extending from a central region of the surface to an outer periphery of the porous body is located. A second groove communicating with the first groove is located in the bearing surface of the base.

With regard to the embodiment of the present disclosure, the following embodiments (2) to (16) will be further disclosed.

(2) In the hydrostatic gas bearing device according to (1), a first intersecting groove intersecting the second groove is located in the bearing surface.

(3) In the hydrostatic gas bearing device according to (1) or (2), at least two of the second grooves are located, and the first intersecting groove connects the second grooves adjacent to each other.

(4) In the hydrostatic gas bearing device according to any one of (1) to (3), the first intersecting groove has an annular shape.

(5) In the hydrostatic gas bearing device according to any one of (1) to (4), the surface of the porous body is flush with the bearing surface of the base.

(6) In the hydrostatic gas bearing device according to any one of (1) to (5), the porous body is made of the same material as that of a member in which the recessed portion is located.

(7) In the hydrostatic gas bearing device according to any one of (1) to (6), at least a bottom surface of the porous body is bonded to the recessed portion.

(8) In the hydrostatic gas bearing device according to (7) above, the porous body is bonded to an entire surface of the recessed portion other than an opening portion of the gas supply hole.

(9) In the hydrostatic gas bearing device according to any one of (1) to (8), at least two first grooves are located, and angles formed by adjacent two first grooves are the same.

(10) In the hydrostatic gas bearing device according to any one of (1) to (9), a second intersecting groove intersecting the first groove is further located in the porous body.

(11) In the hydrostatic gas bearing device according to any one of (1) to (10), one or more recessed portions are located in the bearing surface, and one or more porous bodies are located in the respective one or more recessed portions.

(12) In the hydrostatic gas bearing device described in (11), when one of the porous bodies, the first groove located in one of the porous bodies porous body, the second groove communicating with the first groove, and the first intersecting groove intersecting the second groove are regarded as one unit, one or more units are located in the bearing surface, and units adjacent to each other share at least part of the second groove or at least part of the first intersecting groove and are connected.

(13) In the hydrostatic gas bearing device described in (11), when one of the porous bodies, the first groove located in the one of the porous bodies, the second groove communicating with the first groove, and the first intersecting groove intersecting the second groove are regarded as one unit, one or more units are located in the bearing surface, and each of the one or more units is independent while not contacting each other.

(14) In the hydrostatic gas bearing device described in (13), for at least two of the units, the units adjacent to each other are connected via a communication groove.

(15) In the hydrostatic gas bearing device described in any one of (1) to (14), arithmetic mean roughness Ra of the bearing surface of the base is smaller than arithmetic mean roughness Ra of an inner wall surface of the second groove.

(16) In the hydrostatic gas bearing device according to any one of (1) to (15), arithmetic mean roughness Ra of the surface of the porous body is smaller than arithmetic mean roughness Ra of an inner wall surface of the first groove.

### REFERENCE SIGNS

1 Movable member
1a Bearing surface of base of movable member
11 Recessed portion
11a Bottom surface of recessed portion
12 Gas supply hole
12a Opening portion of gas supply hole
2 Fixed member
2a Bearing surface of base of fixed member
3 Porous body
3a Another porous body
41 First groove
41a Another first groove
42 Second groove
51 First intersecting groove
52 Second intersecting groove
53 Communication groove
54 Shared groove

1. A hydrostatic gas bearing device, comprising:
a movable member: and
a fixed member,
wherein a recessed portion is located at a bearing surface of a base of the movable member or the fixed member, and an opening portion of a gas supply hole is located at a bottom surface of the recessed portion,
a porous body serving as a gas ejection portion is located in the recessed portion while not protruding from the bearing surface,
in a surface of the porous body, a first groove extending from a central region of the surface to an outer periphery of the porous body is located, and
a second groove communicating with the first groove is located in the bearing surface of the base.

2. The hydrostatic gas bearing device according to claim 1, wherein a first intersecting groove intersecting the second groove is located in the bearing surface.

3. The hydrostatic gas bearing device according to claim 2, wherein
at least two of the second grooves are located, and
the first intersecting groove connects the second grooves adjacent to each other.

4. The hydrostatic gas bearing device according to claim 1, wherein the first intersecting groove has an annular shape.

5. The hydrostatic gas bearing device according to claim 1, wherein the surface of the porous body is flush with the bearing surface of the base.

6. The hydrostatic gas bearing device according to claim 1, wherein the porous body is made of the same material as that of a member in which the recessed portion is located.

7. The hydrostatic gas bearing device according to claim 1, wherein at least a bottom surface of the porous body is bonded to the recessed portion.

8. The hydrostatic gas bearing device according to claim 7, wherein the porous body is bonded to an entire surface of the recessed portion other than an opening portion of the gas supply hole.

9. The hydrostatic gas bearing device according to claim 1, wherein
at least two first grooves are located, and
angles formed by adjacent two first grooves are the same.

10. The hydrostatic gas bearing device according to claim 1, wherein a second intersecting groove intersecting the first groove is further located in the porous body.

11. The hydrostatic gas bearing device according to claim 1, wherein
one or more recessed portions are located in the bearing surface, and
one or more porous bodies are located in the respective one or more recessed portions.

12. The hydrostatic gas bearing device according to claim 11, wherein when one of the porous bodies, the first groove located in the one of the porous bodies, the second groove communicating with the first groove, and the first intersecting groove intersecting the second groove are regarded as one unit, one or more units are located in the bearing surface, and units adjacent to each other share at least part of each of the units and are connected.

13. The hydrostatic gas bearing device according to claim 11, wherein when one of the porous bodies, the first groove located in the one of the porous bodies, the second groove communicating with the first groove, and the first intersecting groove intersecting the second groove are regarded as one unit, one or more units are located in the bearing surface, and each of the one or more units is independent while not contacting each other.

14. The hydrostatic gas bearing device according to claim 13, wherein for at least two of the units, the units adjacent to each other are connected via a communication groove.

15. The hydrostatic gas bearing device according to claim 1, wherein arithmetic mean roughness Ra of the bearing surface of the base is smaller than arithmetic mean roughness Ra of an inner wall surface of the second groove.

16. The hydrostatic gas bearing device according to claim 1, wherein arithmetic mean roughness Ra of the surface of the porous body is smaller than arithmetic mean roughness Ra of an inner wall surface of the first groove.
